(19) United States
(12) Patent Application Publication
(10) Pub. No.: US 2026/0047387 A1
(43) Pub. Date: Feb. 12, 2026

(54) TRANSFERRING MODULE AND SUBSTRATE TREATING APPARATUS COMPRISING THE SAME

(71) Applicant: SEMES CO., LTD., Cheonan-si (KR)

(72) Inventors: Ki Sang EUM, Cheonan-si (KR); Hak Jun KIM, Asan-si (KR); Tae Hoon LEE, Suwon-si (KR)

(21) Appl. No.: 19/231,426

(22) Filed: Jun. 7, 2025

(30) Foreign Application Priority Data
Aug. 6, 2024 (KR) 10-2024-0104316

(51) Int. Cl. H01L 21/677; H01L 21/683

(52) U.S. Cl. CPC H01L 21/67766; H01L 21/6838

(57) ABSTRACT

A transferring module includes a support plate on which a substrate is supported, and an adsorption portion disposed on the support plate, adsorbing and fixing a lower surface of the substrate, and including a groove formed inwardly concavely in one direction in an outer peripheral surface.

### CROSS-REFERENCE TO RELATED APPLICATION(S)

This application claims benefit of priority to Korean Patent Application No. 10-2024-0104316 filed on Aug. 6, 2024 in the Korean Intellectual Property Office, the disclosure of which is incorporated herein by reference in its entirety.

### BACKGROUND

### 1. Field

The present disclosure relates to a transferring module and a substrate treating apparatus including the same.

### 2. Description of Related Art

When manufacturing semiconductor devices or display devices, various processes such as photography, etching, ashing, ion implantation, thin film deposition, cleaning and the like are performed. To perform these various processes, the substrate is transferred by a transferring module including a transfer robot. The transferring module may pick up and transfer the substrate by vacuum holding, for example.

Recently, as semiconductor manufacturing processes have become more detailed and complex, when transferring the substrate by vacuum holding, the existing transfer robot may only perform suction at the level of several hundred μm due to the limitations of a pad structure thereof, and accordingly, there may be a problem that sufficient suction is not exerted due to the curved shape of the lower surface of the substrate due to the warpage phenomenon.

### SUMMARY

An aspect of the present disclosure is to provide a transferring module capable of providing sufficient suction force when returning a substrate to a warped wafer of several thousand μm or more, and a substrate treating apparatus including the same.

According to an aspect of the present disclosure, a transferring module includes a support plate on which a substrate is supported, and an adsorption portion disposed on the support plate, adsorbing and fixing a lower surface of the substrate, and including a groove formed inwardly concavely in one direction in an outer peripheral surface.

According to an aspect of the present disclosure, a substrate treating apparatus includes a module body, an index robot disposed in the module body, and including a support plate on which a substrate is supported, and an adsorption portion disposed on the support plate, adsorbing and fixing a lower surface of the substrate, having a multilayer structure including an elastic material, and having a groove formed inwardly concavely in one direction from an outer peripheral surface, and a vacuum module including a vacuum path connected to the adsorption portion, and a vacuum pump connected to the vacuum path and providing vacuum pressure for adsorbing and fixing the substrate.

According to an aspect of the present disclosure, a substrate treating apparatus includes a load port including a loading platform on which a substrate is disposed, a buffer module including a buffer capable of storing the substrate, and a transferring module disposed between the load port and the buffer module and transferring the substrate between the loading platform and the buffer module. The transferring module includes a module body, an index robot disposed in the module body, and including a support plate on which a substrate is supported and an adsorption portion disposed on the support plate, adsorbing and fixing a lower surface of the substrate, and having a groove formed inwardly concavely in one direction in an outer peripheral surface, and a vacuum module including a vacuum path connected to the adsorption portion, and a vacuum pump connected to the vacuum path and providing vacuum pressure for adsorbing and fixing the substrate. The adsorption portion includes a first pad layer coupled to the support plate, a second pad layer stacked on and coupled to the first pad layer, and a third pad layer stacked on and coupled to the second pad layer and contacting a lower surface of the substrate when the substrate is adsorbed and fixed, wherein the second pad layer has greater elasticity than elasticity of the first pad layer and the third pad layer. The second pad layer includes a first region having a first thickness, and a second region surrounding an outer side of the first region and having a second thickness, greater than the first thickness. The groove is concave inwardly in a radial direction of the adsorption portion from an outer peripheral surface of the second pad layer, and extends in a circumferential direction of the second pad layer while being disposed within the second region.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a drawing of a substrate treating apparatus viewed from above;

FIG. 2 is a drawing of the substrate treating apparatus of FIG. 1 viewed in the A-A direction;

FIG. 3 is a drawing of the substrate treating apparatus of FIG. 1 viewed in the B-B direction;

FIG. 4 is a schematic perspective view of a transferring module according to an embodiment;

FIG. 5 is a perspective view of an adsorption portion according to an embodiment;

FIG. 6 is a cross-sectional view of the adsorption portion of FIG. 5;

FIG. 7 is a cross-sectional view of an adsorption portion viewed along the II-II′ direction of FIG. 4;

FIG. 8A is a cross-sectional view of an adsorption portion according to another embodiment;

FIG. 8B is a cross-sectional view of the adsorption portion according to another embodiment;

FIG. 8C is a cross-sectional view of the adsorption portion according to another embodiment;

FIG. 9A is a cross-sectional view illustrating an adsorption portion according to another embodiment;

FIG. 9B is a cross-sectional view illustrating an adsorption portion according to another embodiment; and

FIG. 10 is a graph illustrating changes in a reaction force generated by applying rotational displacement to an adsorption portion according to embodiments.

### DETAILED DESCRIPTION

Hereinafter, with reference to the attached drawings, example embodiments will be described in detail so that those skilled in the art may easily practice the present disclosure. However, when describing example embodiments in detail, if it is determined that a detailed description of a related known function or configuration may unnecessarily obscure the gist of the present disclosure, the detailed description may be omitted. In addition, the same symbols may be used throughout the drawings for parts that perform similar functions and actions. In addition, in this specification, terms such as “on,” “upper portion,” “upper side,” “upper surface,” “upper wall surface,” “below,” “lower portion,” “lower side,” “lower surface,” and “lower wall surface” are based on the drawings, and terms such as “inside,” “outside,” and “the other” are based on the outer surface of the corresponding component, and may actually vary depending on the direction in which the elements or components are disposed.

Additionally, throughout the specification, reference to an element being “included” may mean that it may include other elements, rather than excluding other elements, unless otherwise specifically stated.

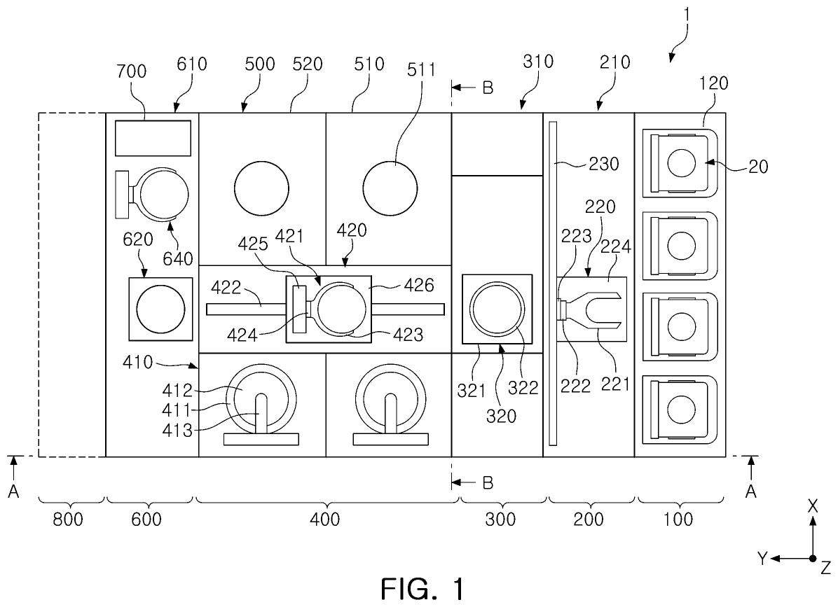

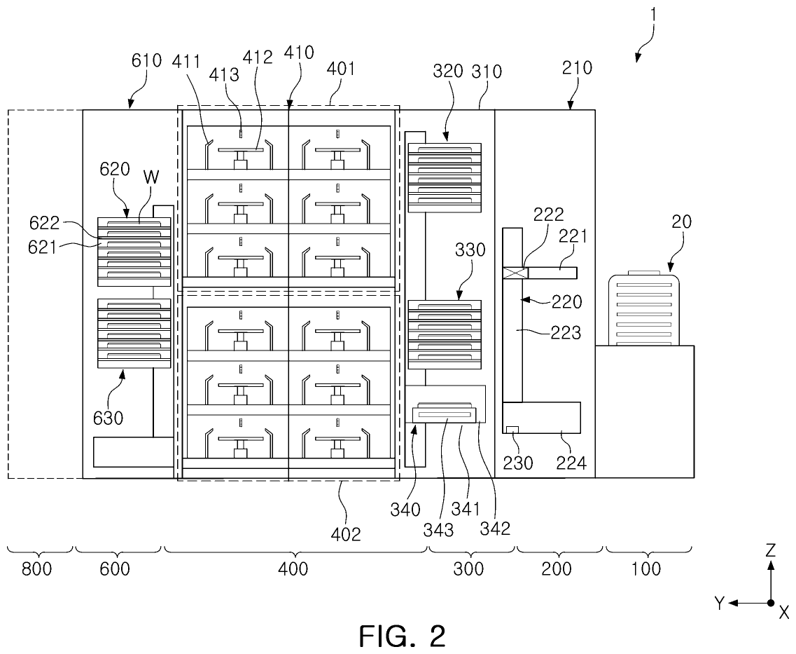

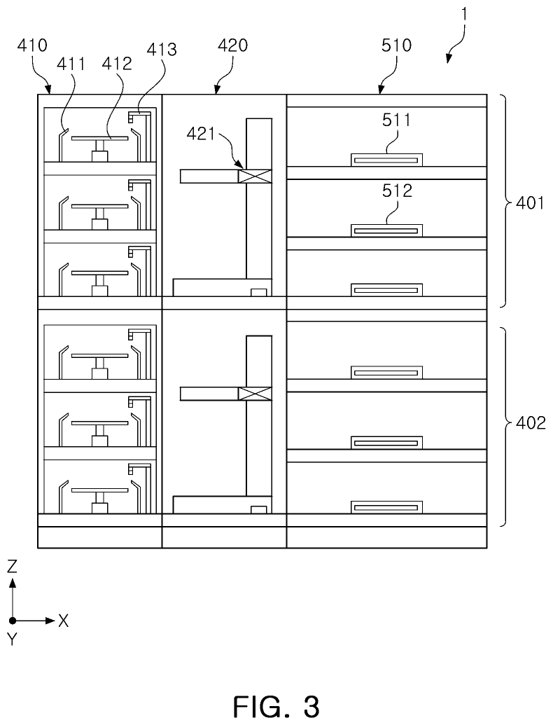

FIG. 1 is a drawing of a substrate treating apparatus viewed from above, FIG. 2 is a drawing of the substrate treating apparatus of FIG. 1 viewed in the A-A′ direction, and FIG. 3 is a drawing of the substrate treating apparatus of FIG. 1 viewed in the B-B′ direction.

Referring to FIGS. 1 to 3, a substrate treating apparatus 1 may include a load port 100, an index module 200, a buffer module 300, an application and development module 400, and a purge module 700. The load port 100, the index module 200, the buffer module 300, the application and development module 400, and the interface module 600 may be sequentially disposed in a row in one direction. The purge module 700 may be provided within the interface module 600. In contrast, the purge module 700 may be provided in various locations, such as the location in which the exposure device is connected at the rear end of the interface module 600 or the side of the interface module 600.

Hereinafter, the direction in which the load port 100, the index module 200, the buffer module 300, the application and development module 400, and the interface module 600 are disposed is referred to as the first direction (Y), the direction perpendicular to the first direction (Y) when viewed from above is referred to as the second direction (X), and the directions perpendicular to the first direction (Y) and the second direction (X) may be referred to as the third direction (Z).

The substrate (W) may be moved while being stored in the cassette 20. The cassette 20 may have a structure that may be sealed from the outside. For example, a front open unified pod (FOUP) having a door at the front may be used as the cassette 20.

Below, the load port 100, the index module 200, the buffer module 300, the application and development module 400, the interface module 600, and the purge module 700 may be described in detail.

The load port 100 may include a loading platform 120 on which a cassette 20 containing a substrate (W) is disposed. A plurality of loading platforms 120 are provided, and the loading platforms 120 may be disposed in a row along the second direction (X). In FIG. 2, an example in which four loading platforms 120 are provided is illustrated, but the number may be changed.

The index module 200 may transfer the substrate (W) between the cassette 20 disposed on the loading platform 120 of the load port 100 and the buffer module 300. The index module 200 may include an index body 210, an index robot 220, and a guide rail 230.

The module body 210 is generally in the shape of a rectangular solid with an empty interior, and may be formed by connecting a plurality of frames. The module body 210 may be disposed between the load port 100 and the buffer module 300. At this time, the module body 210 may be provided at a lower height than the frame 310 of the buffer module 300.

The index robot 220 and the guide rail 230 may be disposed inside the module body 210. The index robot 220 is a part that returns a substrate (W), and may include a hand 221, an arm 222, and a support 223. In addition, the index robot 220 may further include a pedestal 224.

The hand 221 may directly handle the substrate (W). The hand 221 may be in the form of a support plate, which will be described later. At this time, the hand 221 may be provided to be movable in the first direction (Y), the second direction (X), and the third direction (Z). In addition, the hand 221 may be provided to be rotatable.

The hand 221 may be fixedly installed to the arm 222. At this time, the arm 222 may be provided as an elastic structure and a rotatable structure.

The support 223 may be extended along the third direction (Z). The arm 222 may be coupled to the support 223. The arm 222 may be coupled to the support 223 to be reciprocally movable along the longitudinal direction (for example, the third direction) (Z) of the support 223. At this time, the support 223 may be fixedly connected to the pedestal 224.

The guide rail 230 may be extended along the second direction (X). The pedestal 224 may be connected to the guide rail 230. In this case, the pedestal 224 may move linearly along the guide rail 230 in the second direction (X). In addition, although not illustrated in the drawing, the module body 210 may further include a door opener for opening and closing the door of the cassette 20.

In addition, the index robot 220 may include a support plate 221 on which the substrate (W) is supported when transferring the substrate (W), and an adsorption portion (Ab) that adsorbs and fixes the lower surface of the substrate (W) supported on the support plate 221. In addition, a vacuum module may be connected to the index robot 220. The vacuum module may include a vacuum pump (P) that provides suction force to the adsorption portion (Ab) and a vacuum path (U). Hereinafter, an apparatus including the index robot 220 and the vacuum module will be referred to as a ‘transferring module (TU)’.

The buffer module 300 may include a frame 310, a first buffer 320, a second buffer 330, and a cooling chamber 340. The frame 310 may be provided in the shape of a rectangular solid with an empty interior. The buffer module 300 may be disposed between the index module 200 and the application and development module 400. The first buffer 320, the second buffer 330, and the cooling chamber 340 may be positioned within the frame 310. The cooling chamber 340, the second buffer 330, and the first buffer 320 may be sequentially disposed from below along the third direction (Z). The first buffer 320 may be positioned at a height corresponding to the application module 401 of the application and development module 400, and the second buffer 330 and the cooling chamber 340 may be provided at a height corresponding to the development module 402 of the application and development module 400.

The first buffer 320 and the second buffer 330 may each temporarily store a plurality of substrates (W). The first buffer 320 may have a housing 321 and a plurality of supports 322. In the first buffer 320, the supports 322 may be disposed within the housing 321 and provided to be spaced apart from each other along a third direction (Z). The second buffer 330 may have a housing 331 and a plurality of supports 332. In the second buffer 330, the supports 332 may be disposed within the housing 331 and provided to be spaced apart from each other along a third direction (Z). One substrate (W) is disposed on each support 322 of the first buffer 320 and each support 332 of the second buffer 330. The housing 331 may have an opening in the direction in which the index robot 220 is provided so that the index robot 220 may load or unload a substrate (W) into or from the support 332 within the housing 331. The first buffer 320 may have a structure generally similar to that of the second buffer 330. However, the housing 321 of the first buffer 320 may have an opening in the direction in which the first buffer robot 360 is provided and in the direction in which the coating robot 421 positioned in the application module 401 is provided. The number of supports 322 provided in the first buffer 320 and the number of supports 332 provided in the second buffer 330 may be the same or different. In one example, the number of supports 332 provided in the second buffer 330 may be greater than the number of supports 322 provided in the first buffer 320.

Each cooling chamber 340 may cool a substrate (W). The cooling chamber 340 may include a housing 341 and a cooling plate 342. The cooling plate 342 may have an upper surface on which the substrate (W) is disposed and a cooling unit 343 for cooling the substrate (W). Various methods may be used in the cooling unit 343, such as cooling using cooling water or cooling using a thermoelectric element.

In addition, a lift pin assembly for positioning the substrate (W) on the cooling plate 342 may be provided in the cooling chamber 340. The housing 341 may have an opening in the direction in which the index robot 220 is provided and in the direction in which the development robot is provided so that the development robot provided in the index robot 220 and the development module 402 may load or unload the substrate (W) onto or from the cooling plate 342. In addition, the cooling chamber 340 may be provided with doors for opening and closing the above-described opening.

In the above, the buffer module 300 has been described as an embodiment including the configuration of the cooling chamber 340, but the present disclosure is not limited thereto, and the configuration of the cooling chamber 340 may be omitted as needed.

The application module 401 may perform a process of applying a photosensitive liquid such as a photoresist to a substrate (W) and a heat treatment process such as heating and cooling the substrate (W) before and after the resist application process. The application module 401 may have a coating chamber 410, a heat treatment chamber portion 500, and a return chamber 420. The coating chamber 410, the return chamber 420, and the heat treatment chamber portion 500 may be sequentially disposed along the second direction (X). For example, with respect to the return chamber 420, the coating chamber 410 may be provided on one side of the return chamber 420, and the heat treatment chamber portion 500 may be provided on the other side of the return chamber 420.

A plurality of coating chambers 410 may be provided, and each may be provided in a plurality in the third direction (Z). In addition, the coating chamber 410 may be provided in a plurality in the first direction (Y) as illustrated in FIG. 1, or may be provided in one in the first direction (Y). The heat treatment chamber portion 500 includes a baking chamber 510 and a cooling chamber 520, and the baking chamber 510 and the cooling chamber 520 may be respectively provided in a plurality in the third direction (Z). The return chamber 420 may be positioned parallel to the first buffer 320 of the first buffer module 300 in the first direction 12. An coating robot 421 and a guide rail 422 may be positioned within the return chamber 420. The return chamber 420 may have a generally rectangular shape. The coating robot 421 may transfer the substrate (W) between the baking chamber 510, the cooling chamber 520, the coating chamber 410, and the first buffer 320 of the first buffer module 300.

The guide rail 422 may be disposed so that the length direction thereof is parallel to the first direction (Y). The guide rail 422 may guide the coating robot 421 to move in a straight line in the first direction (Y). The coating robot 421 may have a hand 423, an arm 424, a support 425, and a base 426. The hand 423 may be fixedly installed to the arm 424. The arm 424 may be provided with a flexible structure so that the hand 423 may move in a horizontal direction. The support 425 may be provided so that the longitudinal direction thereof is disposed along the third direction (Z). The arm 424 may be coupled to the support 425 to be linearly movable in the third direction (Z) along the support 425. The support 425 may be fixedly coupled to the base 426, and the base 426 may be coupled to the guide rail 422 to be movable along the guide rail 422.

The coating chambers 410 may all have the same structure, but the types of treatment liquids used in respective coating chambers 410 may be different from each other. The treatment liquid may be a treatment liquid for forming a photoresist film or an anti-reflection film.

The coating chamber 410 may apply the treatment liquid onto the substrate (W). In the coating chamber 410, a treatment unit including a treatment container 411, a support member 412, and a nozzle member 413 may be provided.

For example, in the coating chamber 410, one treatment unit is disposed along the first direction (Y), but this is not limited thereto, and two or more treatment units may be disposed in one coating chamber 410. respective treatment units may have the same structure. However, the types of treatment liquids used in respective treatment units may be different from each other.

The treatment container 411 of the coating chamber 410 may have a shape with an open top. The support member 412 is positioned within the treatment container 411 and may support the substrate (W). The support member 412 may be provided to be rotatable. The nozzle member 413 may supply the treatment liquid onto the substrate (W) disposed on the support member 412. The treatment liquid may be applied to the substrate (W) by spin coating. In addition, the coating chamber 410 may optionally be provided with a nozzle (not illustrated) for supplying a cleaning solution such as deionized water (DIW) to clean the surface of the substrate (W) to which the treatment solution has been applied, and a back rinse nozzle (not illustrated) for cleaning the lower surface of the substrate (W).

In the baking chamber 510, the substrate (W) may be heat-treated when the substrate (W) is settled by the coating robot 421.

In the baking chamber 510, a prebake process for removing organic substances or moisture from the surface of the substrate (W) by heating the substrate (W) to a predetermined temperature before applying the treatment solution, or a soft bake process for removing the organic substances or moisture from the surface of the substrate (W) after applying the treatment solution on the wafer (W), and a cooling process for cooling the substrate (W) after respective heating processes, and the like may be performed.

The baking chamber 510 may be equipped with a heating plate 511 and a cooling plate 512. A cooling unit such as cooling water or a thermoelectric element may be provided in the cooling plate 512.

In the cooling chamber 520, a cooling process for cooling the substrate (W) before applying the treatment solution may be performed. The cooling chamber 520 may be equipped with a cooling plate. The cooling plate may include a cooling unit that may be used in various ways, such as cooling by cooling water or cooling by using a thermoelectric element, to cool the substrate (W).

The interface module 600 may connect the application and development module 400 to an external exposure device 800. The interface module 600 includes an interface frame 610, a first interface buffer 620, a second interface buffer 630, and a return robot 640. The return robot 640 may return the substrate returned to the first and second interface buffers 620 and 630 after the application and development module 400 is terminated to the exposure device 800. The first and second interface buffers 620 include a housing 621 and a support 622. The return robot 640 and the coating robot 421 may load/unload the substrate (W) to/from the support 622.

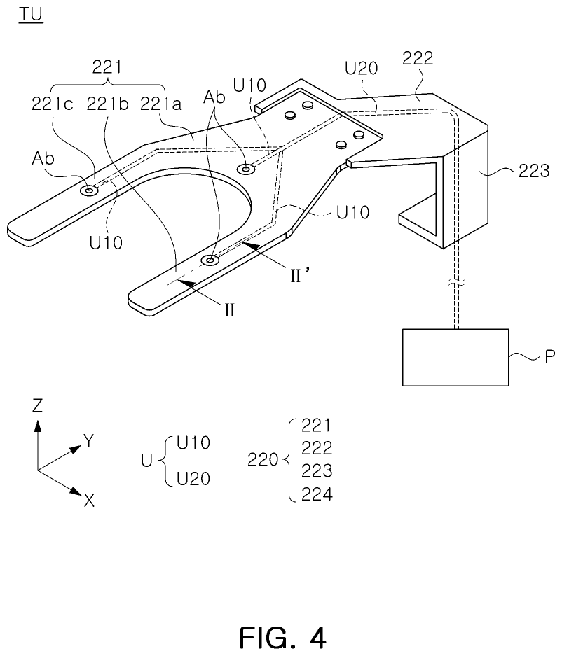

FIG. 4 is a schematic perspective view illustrating a transferring module according to an embodiment.

Referring to FIG. 4, the transferring module (TU) is a device for returning the substrate (W) and may include an index robot 220. As described above, the index robot 220 may be disposed within the module body 210. At this time, the index robot 220 may move in a straight line in the second direction (X) along the guide rail 230 within the module body 210. In addition, as described above, the index robot 220 may be provided to be rotatable between the load port 100 and the buffer module 300. To this end, the transferring module (TU) may include a linear driving unit (not illustrated) and a rotational driving unit (not illustrated).

The index robot 220 may include a support plate 221 and an adsorption portion (Ab). In addition, the index robot 220 may further include an arm 222 and a support 223.

The support plate 221 is a portion that supports the substrate (W) and may be the hand 221 described above. At this time, supporting the substrate (W) does not mean supporting in a state of direct contact with the lower surface of the substrate (W), and when supporting the substrate (W), the portion that comes into contact with the lower surface of the substrate (W) may be the adsorption portion (Ab).

The support plate 221 may have various shapes. For example, the support plate 221 may have a ‘U’ shape including a plate body 221a and two support bars 221b and 221c. At this time, the two support bars will be referred to as the first support bar 221b and the second support bar 221c, respectively. In this case, one end of the plate body 221a may be fixedly connected to the arm 222. In addition, at the other end of the plate body 221a, the first support bar 221b and the second support bar 221c having the same shape and size may be disposed to face each other. Hereinafter, the description will focus on the case where the support plate 221 is in the ‘U’ shape as described above, but the present disclosure is not limited thereto.

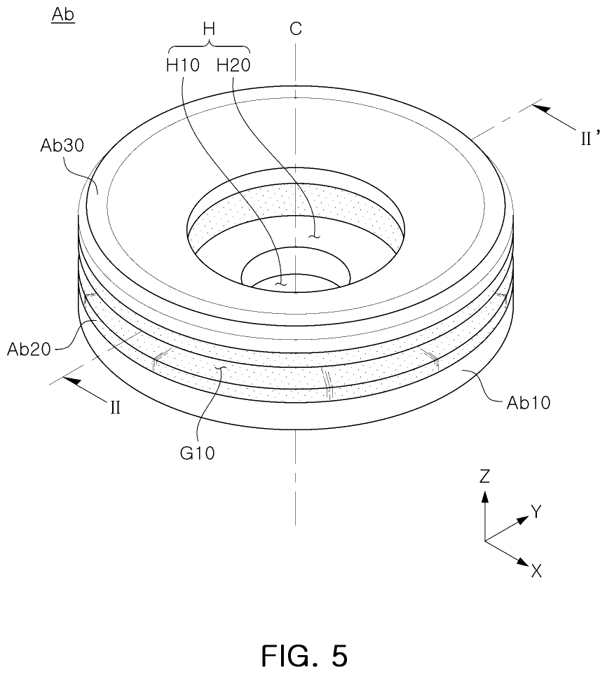

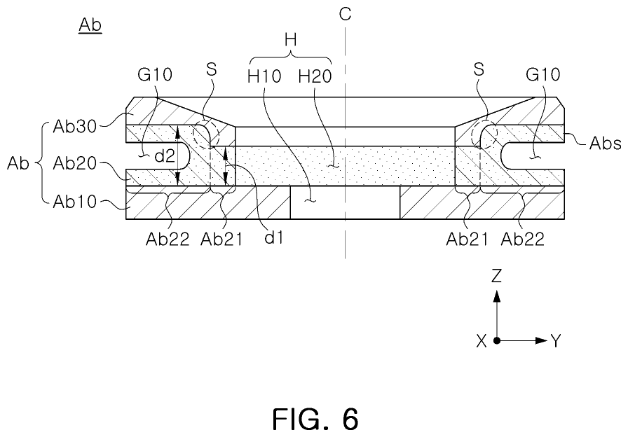

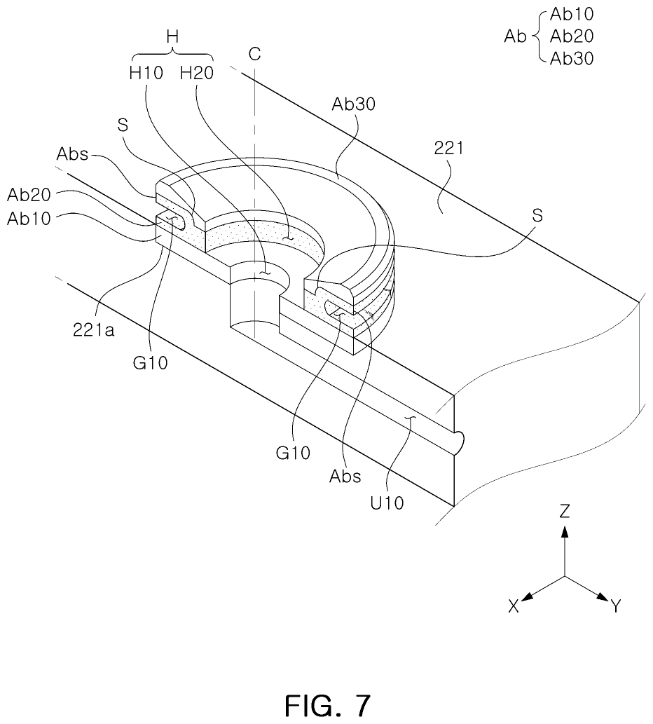

FIG. 5 is a perspective view illustrating an adsorption portion according to an embodiment. FIG. 6 is a cross-sectional view illustrating the adsorption portion of FIG. 5. FIG. 7 is a cross-sectional view illustrating the adsorption portion as viewed along the II-II′ direction of FIG. 4.

Referring to FIGS. 5 and 6, the adsorption portion (Ab) according to an embodiment (hereinafter, Embodiment 1) may be disposed on the support plate 221. The adsorption portion (Ab) may be disposed such that at least a portion of the upper portion thereof protrudes upward from the support plate 221. Accordingly, when the substrate (W) is supported by the support plate 221, the lower surface of the substrate (W) may be in direct contact with the adsorption portion (Ab).

The adsorption portion (Ab) may have various shapes. For example, the adsorption portion (Ab) may have a shape similar to a cylinder having a circular cross-section when viewed from the upper side thereof (for example, in the XY plane direction). At this time, the adsorption portion (Ab) may include a hollow portion (H) extending from the upper end thereof to the lower end along the third direction (Z). The adsorption portion (Ab) may have a shape in which the center (C) thereof is penetrated by the hollow portion (H).

The adsorption portion (Ab) may have a multilayer structure. For example, the adsorption portion (Ab) may include a first pad layer Ab10, a second pad layer Ab20, and a third pad layer Ab30. In this case, the adsorption portion (Ab) may be formed by stacking a second pad layer Ab20 on a first pad layer Ab10, stacking a third pad layer Ab30 on the second pad layer Ab20, and then coupling respective pad layers Ab10, Ab20, Ab30 to each other.

Through-holes H10 and H20 penetrating the center (C) along the third direction (Z) may be respectively formed in the first pad layer Ab10, the second pad layer Ab20, and the second pad layer Ab20. As the pad layers Ab10, Ab20 and Ab30 are stacked and coupled, the through-holes H10 and H20 may also be connected in a coaxial arrangement in a single row along the third direction (Z). In this way, the hollow portion (H) described above may be formed by connecting the through-holes H10 and H20. At this time, the through-hole H10 provided in the first pad layer Ab10 may have a smaller diameter than that of the other through-hole H20.

The first pad layer Ab10, the second pad layer Ab20, and the third pad layer Ab30 may be combined in various ways. For example, the first pad layer Ab10, the second pad layer Ab20, and the third pad layer Ab30 may be combined using an adhesive, but the present disclosure is not limited thereto.

In the case of the adsorption portion (Ab) according to Embodiment 1, the second pad layer Ab20 may include a plurality of regions having different thicknesses.

For example, the second pad layer Ab20 may include a first region Ab21 having a first thickness d1 and a second region Ab22 having a second thickness d2. At this time, the first region Ab21 may be an inner region disposed to surround a hollow portion (H). In addition, the second region Ab22 may be an outer region connected to a radially outer side of the first region Ab21 and surrounding the first region Ab21 in the circumferential direction of the second pad layer Ab20. In this case, the second thickness d2 may be greater than the first thickness. Accordingly, a step portion (S) may be formed between the first region Ab21 and the second region Ab22. In this way, since the second pad layer Ab20 includes the step portion (S), the contact area with the third pad layer Ab30 increases, and thus the bonding strength with the third pad layer Ab30 may be improved.

In addition, based on the radial direction of the adsorption portion (Ab) or the second pad layer Ab20, the second region Ab22 may be formed to have a longer length than the first region Ab21. Accordingly, the second region Ab22 may have a wider area than that of the first region Ab21. Accordingly, the second region Ab22 may secure an area sufficient for forming a groove G10 to be described later.

Meanwhile, the second pad layer Ab20 may include three or more regions having different thicknesses, but for the convenience of the following description, the case in which the first region Ab21 and the second region Ab22 are included as described above will be described.

When the adsorption portion (Ab) is coupled to the support plate 221, the first pad layer Ab10 may be directly coupled to the support plate 221. At this time, a coupling groove 221a that is concave inwardly from the upper surface of the support plate 221 may be formed. The first pad layer Ab10 may be fixedly coupled to the support plate 221 while being accommodated within the coupling groove 221a. For example, the first pad layer Ab10 may be disposed to be completely accommodated within the coupling groove 221a, and the second pad layer Ab20 and the third pad layer Ab30 may be disposed to protrude upward from the coupling groove 221a. At this time, the upper surface of the first pad layer Ab10 may be disposed at the same or similar height as the upper surface of the support plate 221.

The first pad layer Ab10, the second pad layer Ab20, and the third pad layer Ab30 may have different elasticities. In more detail, the second pad layer Ab20 may have lower elasticity than that of the first pad layer Ab10 and the third pad layer Ab30. To this end, respective pad layers Ab10, Ab20 and Ab30 may be made of different materials. For example, the first pad layer Ab10 may be manufactured from Stainless Steel (SUS). In addition, the third pad layer Ab30 may be manufactured from a material with high heat resistance and wear resistance, such as PEEK, TFE, PTFE, PFA, or the like. At this time, the second pad layer Ab20 may be an elastic body manufactured from silicon rubber having higher elasticity than that of the first pad layer Ab10 and the second pad layer Ab20.

In this way, the adsorption portion (Ab) may improve the bonding strength with the support plate 221 because the first pad layer Ab10 is made of SUS. Since the third pad layer Ab30 in direct contact with the substrate (W) has high heat resistance and wear resistance, damage caused by friction with the substrate (W) or a high-temperature environment of the substrate processing process during the transferring process may be significantly reduced. In addition, since the second pad layer Ab20 is made of a material having greater elasticity than the other pad layers Ab10 and Ab30, the flexibility of the adsorption portion (Ab) may be improved, which will be described later.

The adsorption portion (Ab) may include a groove (hereinafter, a first groove G10). The first groove G10 may be a concave groove shape in the direction facing inward on the outer peripheral surface (Abs) of the adsorption portion (Ab). In this case, the outer peripheral surface (Abs) may be the outer side surface of the adsorption portion (Ab) having a cylinder-like shape as described above. In addition, the direction facing inward as described above may mean a direction facing radially inward of the adsorption portion (Ab).

The first groove G10 may be disposed on the second pad layer Ab20. In more detail, the first groove G10 may be disposed in the second region Ab22 of the second pad layer Ab20. For example, the first groove G10 may be concave toward the radially inner side of the outer peripheral surface (Abs) of the second pad layer Ab20. In addition, the first groove G10 may extend from the outer peripheral surface (Abs) to a shorter length than the second region Ab22 along the radial direction (for example, Y of FIG. 6). Accordingly, the first groove G10 may not be formed in the first region Ab21 of the second pad layer Ab20.

The first groove G10 may have an open outer end. The first groove G10 may communicate with the outside through the open outer end. At this time, the upper surface and the lower surface of the first groove G10 may extend inwardly in parallel from the open outer end in the radial direction (for example, Y in FIG. 6). In addition, the inner end of the first groove G10 may have a rounded shape with a predetermined radius of curvature toward the center (C) of the adsorption portion (Ab).

The first groove G10 as described above may extend in the circumferential direction (for example, the circumferential direction) of the second pad layer Ab20 or the adsorption portion (Ab). At this time, the first groove G10 may extend in the circumferential direction of the adsorption portion (Ab) so that the two ends meet each other to have a ring-like shape.

As another embodiment, the first groove G10 may be shorter than the entire circumferential length of the adsorption portion (Ab). In this case, at least two first grooves G10 may be provided and spaced apart from each other along the circumference of the second pad layer Ab20. For convenience of explanation, the following description will focus on the case where the first groove G10 is in a ring shape.

By providing the first groove G10, a void space may be formed in the second pad layer Ab20. Accordingly, the flexural rigidity of the second pad layer Ab20 may be reduced compared to the case where the first groove G10 is not provided.

Referring again to FIGS. 4 and 7, the index robot 220 may be equipped with a vacuum path (U). The vacuum path (U) may be in the form of a first flow path U10 and a second flow path U20 being connected.

The first flow path U10 may be extended into the interior of the support plate 221. One end of the first flow path U10 may be connected to the hollow portion (H) of the adsorption portion (Ab) through the coupling groove 221a. In addition, the other end of the first flow path U10 may be connected to one end of the second flow path U20. At this time, the other end of the second flow path U20 may be extended into the interior of the arm 222 and the support 223 and may be connected to the vacuum pump (P). The vacuum pump (P) may provide vacuum pressure for vacuum adsorption of the lower surface of the substrate (W). The vacuum pressure of the vacuum pump (P) may be provided to the adsorption portion (Ab) through the first flow path U10 and the second flow path U20. Accordingly, when the substrate (W) is disposed on the support plate 221, the lower surface of the substrate (W) may be fixed by being vacuum-absorbed to the adsorption portion (Ab).

The adsorption portion (Ab) as described above may be provided in multiple numbers. The multiple adsorption portions (Ab) may be disposed to be distributed on the support plate 221. At this time, the first flow path U10 may be provided in multiple numbers corresponding to the number of adsorption portions (Ab).

For example, as illustrated in the drawing, the transferring module (TU) may include three adsorption portions (Ab). In this case, three adsorption portions (Ab) may be disposed one each on the first support bar 221b, the second support bar 221c, and the plate body 221a. At this time, three first flow paths U10 are also provided, and may be connected to the three adsorption portions (Ab), respectively. In addition, the first flow paths U10 are connected to the second flow paths U20, and thus may be connected to the vacuum pump (P). When vacuum pressure is generated by the vacuum pump (P), the vacuum pressure may be provided to respective adsorption portions (Ab) through the second flow path U20 and a plurality of first flow paths U10 connected thereto. As a result, several parts of the lower surface of the substrate (W) may be simultaneously vacuum-absorbed and fixed by respective adsorption portions (Ab).

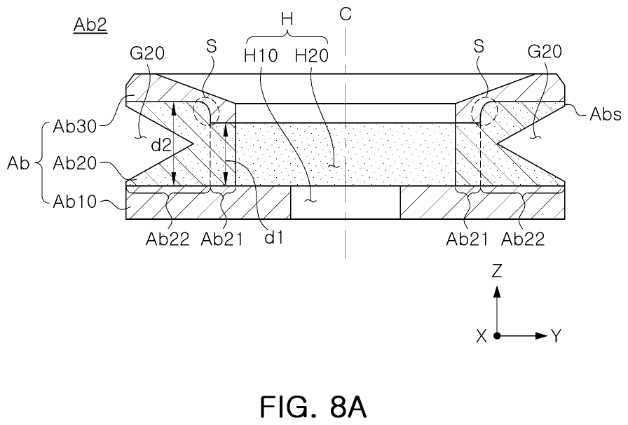

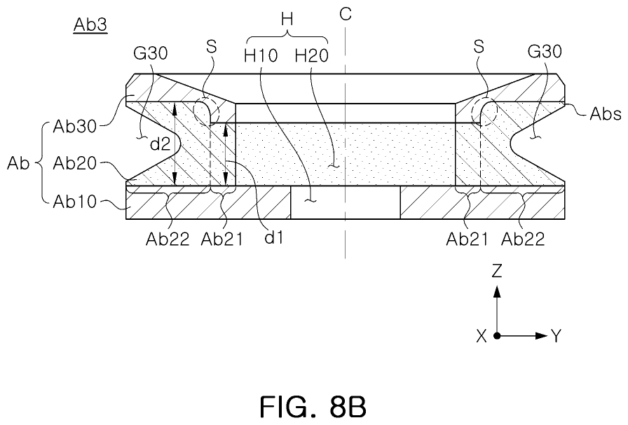

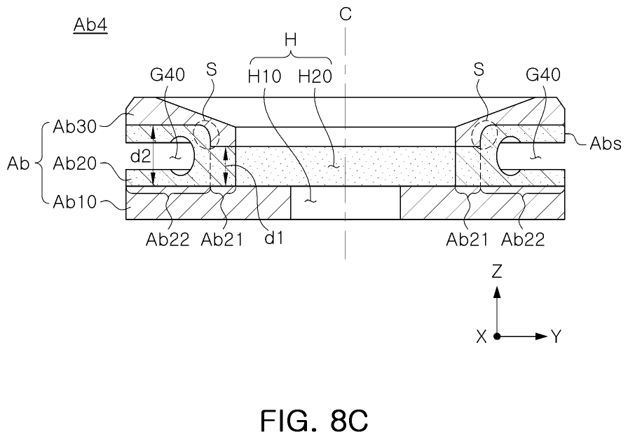

FIG. 8A is a cross-sectional view illustrating an adsorption portion according to another embodiment.

Referring to FIG. 8A, the adsorption portion (hereinafter, a second adsorption portion) Ab2 according to another embodiment (hereinafter, Embodiment 2) may include a hollow portion (H) formed penetrating from the top to the bottom along the third direction (Z) and passing through the center (C).

In addition, the second adsorption portion Ab2 may be formed by stacking and then coupling the first pad layer Ab10, the second pad layer Ab20, and the third pad layer Ab30 in the third direction (Z) together. At this time, the second pad layer Ab20 may have lower elasticity than elasticity of the first pad layer Ab10 and the third pad layer Ab30. In addition, the second pad layer Ab20 includes a first region Ab21 and a second region Ab22 having different thicknesses, which is the same as or similar to the aforementioned embodiment 1, and therefore, a redundant description thereof will be omitted.

The second adsorption portion Ab2 may include a second groove G20. The second groove G20 may be disposed in the second pad layer Ab20. In more detail, the second groove G20 may be disposed in the second region Ab22 of the second pad layer Ab20.

The second groove G20 may have a concave shape in the radially inward direction on the outer peripheral surface (Abs) of the second adsorption portion Ab2. At this time, the second groove G20 may have a shorter length than that of the second region Ab22 based on the radial direction (for example, Y of FIG. 8A). Accordingly, the second groove G20 may be formed within the second region Ab22.

The second groove G20 may be extended so that the upper surface and the lower surface thereof are inclined toward each other at a predetermined angle. Accordingly, the thickness of the second groove G20 may gradually decrease radially inward from the outer peripheral surface (Abs) of the second adsorption portion Ab2. For example, the second groove G20 may have a triangular cross-section when viewed from the side.

The second groove G20 as above may be extended in the circumferential direction (for example, the circumferential direction) of the second pad layer Ab20 or the adsorption portion (Ab), and may have a ring-like shape in which both ends meet each other.

FIG. 8B is a cross-sectional view illustrating an adsorption portion according to another embodiment.

Referring to FIG. 8B, an adsorption portion (hereinafter, a third adsorption portion) Ab3 according to another embodiment (hereinafter, Embodiment 3) may include a hollow portion (H) in the form of a through-hole passing through the center (C) thereof. In addition, the third adsorption portion Ab3 may include a first pad layer Ab10, a third pad layer Ab30, and a second pad layer Ab20 having lower elasticity than the first pad layer Ab10 and the third pad layer Ab30. At this time, the second pad layer Ab20 may include a first region Ab21 and a second region Ab22 having different thicknesses, which are the same as or similar to the above-described embodiment 1 or 2, and therefore, redundant descriptions will be omitted.

The third adsorption portion Ab3 may include a third groove G30. The third groove G30 may be disposed in the second pad layer Ab20. In more detail, the third groove G30 may be disposed in the second region Ab22 of the second pad layer Ab20.

The third groove G30 may have a concave shape toward the radially inward direction in the outer peripheral surface (Abs) of the third adsorption portion Ab3. At this time, the third groove G30 may have a shorter length than that of the second region Ab22 based on the radial direction (for example, Y of FIG. 8B). Thus, the third groove G30 may be formed within the second region Ab22.

The third groove G30 is extended so that the upper surface and the lower surface thereof are inclined toward each other at a predetermined angle, and accordingly, the width of the third groove G30 gradually decreases in thickness as it goes radially inward from the outer peripheral surface (Abs) of the third adsorption portion Ab3, which is the same as in the aforementioned embodiment 2. At this time, unlike in the embodiment 2, the inner end of the third groove G30 may have a rounded shape with a predetermined radius of curvature. For example, the third groove G30 may have a cross-section in the shape of a triangle with one vertex curved when viewed from the side.

The third groove G30 as described above may extend in the peripheral direction (for example, the circumferential direction) of the second pad layer Ab20 or the adsorption portion (Ab), and may have a ring-like shape in which both ends meet each other.

FIG. 8C is a cross-sectional view illustrating an adsorption portion according to another embodiment.

Referring to FIG. 8C, an adsorption portion (hereinafter, a fourth adsorption portion) Ab4 according to another embodiment (hereinafter, Embodiment 4 may include a hollow portion (H) in the form of a through-hole passing through the center (C) thereof. In addition, the fourth adsorption portion Ab4 may include a first pad layer Ab10, a third pad layer Ab30, and a second pad layer Ab20 having lower elasticity than the first pad layer Ab10 and the third pad layer Ab30. At this time, the second pad layer Ab20 may include a first region Ab21 and a second region Ab22 having different thicknesses, which are the same as or similar to the aforementioned embodiment 1, and therefore, a redundant description thereof will be omitted.

The fourth adsorption portion Ab4 may include a fourth groove G40. The fourth groove G40 may be disposed in the second pad layer Ab20. In more detail, the fourth groove G40 may be disposed in the second region Ab22 of the second pad layer Ab20.

The fourth groove G40 may have a concave shape in the radially inward direction in the outer peripheral surface (Abs) of the fourth adsorption portion Ab4. At this time, the fourth groove G40 may have a shorter length than that of the second region Ab22 based on the radial direction (for example, Y in FIG. 8C). Accordingly, the third groove G30 may be formed within the second region Ab22.

The fourth groove G40 may have the upper surface and the lower surface extending inwardly in parallel along the radial direction (for example, Y in FIG. 8C) from the outer peripheral surface (Abs) of the fourth adsorption portion Ab4. At this time, the inner end of the fourth groove G40 may have a circular cross-section having a predetermined diameter when viewed from the side. In this case, the diameter of the inner end of the fourth groove G40 may be larger than the thickness of the outer end. Accordingly, the fourth groove G40 may have a shape in which the area becomes wider at the inner end after being formed with a constant thickness to a predetermined distance inwardly in the radial direction from the outer peripheral surface (Abs).

The fourth groove G40 as described above may extend in the peripheral direction (for example, the circumferential direction) of the second pad layer Ab20 or the adsorption portion (Ab), and may have a ring-like shape in which both ends meet each other.

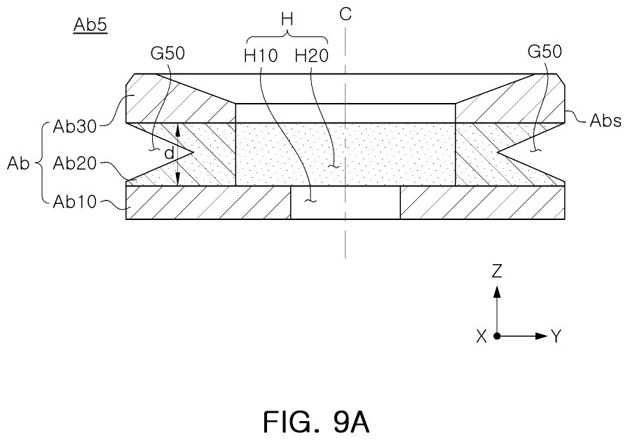

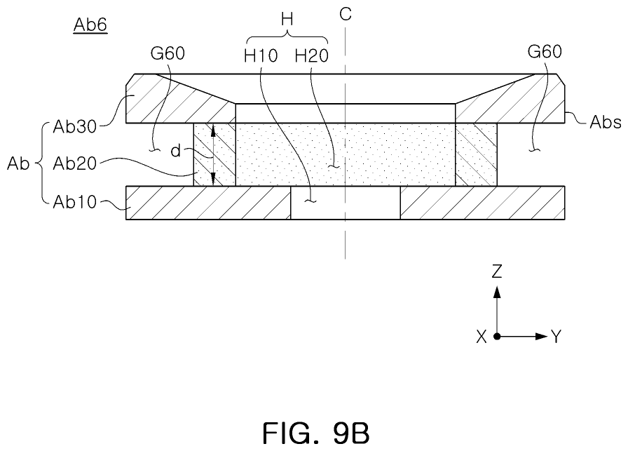

FIG. 9A is a cross-sectional view illustrating an adsorption portion according to another embodiment.

Referring to FIG. 9A, an adsorption portion (hereinafter, the fifth adsorption portion) Ab5 according to another embodiment (hereinafter, Embodiment 5) may include a hollow portion (H) in the form of a through-hole passing through the center (C) thereof. In addition, the fifth adsorption portion Ab5 may include a first pad layer Ab10, a third pad layer Ab30, and a second pad layer Ab20 having lower elasticity than that of the first pad layer Ab10 and the third pad layer Ab30.

Unlike the aforementioned embodiments 1 to 4, in the fifth adsorption portion Ab5, the second pad layer Ab20 may have the same thickness (d) along the radial direction (for example, Y). For example, in the fifth adsorption portion Ab5, the second pad layer Ab20 may be formed as a single region of the same thickness (d).

The fifth adsorption portion Ab5 may include a fifth groove G50. The fifth groove G50 may be disposed in the second pad layer Ab20. At this time, the fifth groove G50 may have a concave shape toward the radially inward direction in the outer peripheral surface (Abs) of the fifth adsorption portion Ab5. At this time, the fifth groove G50 may have a shorter length than the second pad layer Ab20 based on the radial direction (for example, Y of FIG. 9A). Accordingly, the fifth groove G50 may be formed within the second pad layer Ab20.

The fifth groove G50 may have various shapes. For example, the fifth groove G50 may have a triangular cross-section in which the width gradually decreases radially inward from the outer peripheral surface (Abs), as illustrated in FIG. 9A. However, the present disclosure is not limited thereto, and the fifth adsorption portion Ab5 may have the same shape as any one of the aforementioned embodiments 1, 3, or 4.

The fifth groove G50 as described above may extend in the peripheral direction (for example, the circumferential direction) of the second pad layer Ab20 or the adsorption portion (Ab), and may have a shape similar to a ring in which both ends meet each other.

FIG. 9B is a cross-sectional view illustrating an adsorption portion according to another embodiment.

Referring to FIG. 9B, the adsorption portion (hereinafter, the sixth adsorption portion) Ab6 according to another embodiment (hereinafter, Embodiment 6) may include a hollow portion (H) in the form of a through-hole passing through the center (C) thereof. In addition, the sixth adsorption portion Ab6 may include a first pad layer Ab10, a third pad layer Ab30, and a second pad layer Ab20 having lower elasticity than the first pad layer Ab10 and the third pad layer Ab30. At this time, the sixth adsorption portion Ab6, similar to the aforementioned embodiment 5, may be formed as a single region in which the second pad layer Ab20 has the same thickness (d) along the radial direction (for example, Y in FIG. 9B).

The sixth adsorption portion Ab6 may include a sixth groove G60. The sixth groove G60 may be disposed in the second pad layer Ab20. At this time, the sixth groove G60 may have a concave shape toward the radially inward direction on the outer peripheral surface (Abs) of the sixth adsorption portion Ab6.

The sixth groove G60 may have a width (d) equal to the thickness (d) of the second pad layer Ab20 based on the third direction (Z). The sixth groove G60 may extend along the radial direction (for example, Y of FIG. 9B) to a predetermined length. At this time, the sixth groove G60 may be formed to have the same width (d) throughout the entire length thereof. In addition, the sixth groove G60 may be formed within the second pad layer Ab20 by having a shorter length than the second pad layer Ab20.

The sixth groove G60 as above may extend in the peripheral direction (for example, the circumferential direction) of the second pad layer Ab20 or the adsorption portion (Ab) and may have a ring-like shape with both ends meeting each other.

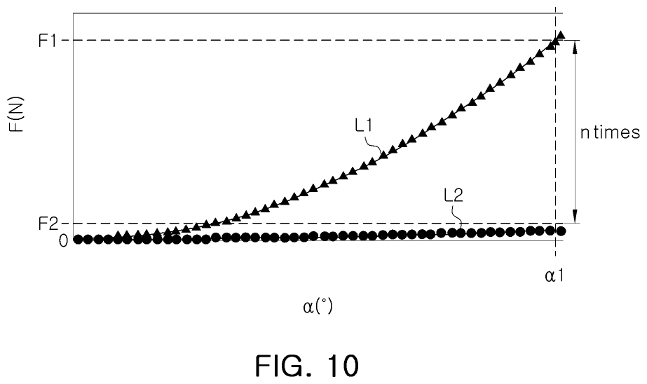

FIG. 10 is a graph illustrating the change in the reaction force generated by applying the rotational displacement to the adsorption portion according to embodiments.

Referring to FIG. 10, when the rotational displacement is applied to the adsorption portions Ab, Ab2, Ab3, Ab4, Ab5 and Ab6 according to embodiments, the reaction force (F) generated in the adsorption portion (Ab) may change depending on the size of the rotational displacement (α). In this case, the rotational displacement may be applied to the adsorption portion Ab, Ab2, Ab3, Ab4, Ab5 or Ab6 while the first pad layer Ab10 is fixedly coupled to the support plate 221. At this time, the rotational displacement (α) may be a ‘rotational angle’ which is the degree to which the adsorption portion Ab, Ab2, Ab3, Ab4, Ab5 or Ab6 rotates around the rotational axis (not illustrated). In addition, the rotation axis may mean a virtual straight line that is parallel to the radial direction (X or Y of the drawing) of the adsorption portion (Ab) and extends to intersect the center (C) of the adsorption portion Ab, Ab2, Ab3, Ab4, Ab5, or Ab6.

‘L1’ of FIG. 10 is a graph illustrating a change in the reaction force that occurs when a predetermined rotational displacement (α) is applied to the adsorption portion (hereinafter, comparative example) (not illustrated) that does not include the groove G10, G20, G30, G40, G50, or G60. In addition, ‘L2’ of FIG. 10 is a graph illustrating a change in the reaction force that occurs when a predetermined rotational displacement (α) is applied to the adsorption portion Ab, Ab2, Ab3, Ab4, Ab5 or Ab6 according to embodiments.

Looking at ‘L2’ of FIG. 10, it can be confirmed that in the case of embodiments including the grooves G10, G20, G30, G40, G50 and G60 as described above, even if the rotational displacement (α) is applied, the reaction force F2 generated in the adsorption portions Ab, Ab2, Ab3, Ab4, Ab5 and Ab6 is very small. In addition, it can be confirmed that even if the rotational displacement (α) increases, the change in the generated reaction force F2 is minimal. In comparison, looking at ‘L1’ of FIG. 10, it can be confirmed that in the case of the comparative example, as the rotational displacement (α) applied to the adsorption portion increases, the generated reaction force F1 significantly increases.

In addition, when comparing the cases where the maximum rotational displacement α1 is applied on the graph of FIG. 10, it can be confirmed that in the comparative example where the groove G10, G20, G30, G40, G50, G60 is not provided, a reaction force F1 that is several to several tens of times greater than that of the embodiments occurs.

For example, in the case of the adsorption portions Ab, Ab2, Ab3, Ab4, Ab5 and Ab6 according to the present disclosure, since the grooves G10, G20, G30, G40, G50 and G60 are formed in the second pad layers Ab20, even if the rotational displacement (α) is applied, only a small reaction force (F) is generated. This means that the adsorption portions Ab, Ab2, Ab3, Ab4, Ab5 and Ab6 according to embodiments of the present disclosure have a weaker flexural rigidity than the comparative example, and thus has excellent flexibility. In addition, in the case of embodiments of the present disclosure, since the second pad layer Ab20 is made of a material having lower elasticity than that of the other pad layers AC10 and AC30, the flexibility described above may be further improved.

In the transferring module (TU) and the substrate treating apparatus 1 including the same according to embodiments as described above, the second pad layers Ab20 of the adsorption portions Ab, Ab2, Ab3, Ab4, Ab5 and Ab6 having a multilayer structure have lower elasticity than that of the other pad layers AC10 and AC30, and since the second pad layers Ab20 are provided with grooves G10, G20, G30, G40, G50 and G60, the bending rigidity may also be reduced (the flexibility may be increased).

Accordingly, even in the case of a substrate (W) in which a warpage phenomenon of several thousand μm or more has occurred, the adsorption portion Ab, Ab2, Ab3, Ab4, Ab5, Ab6 may be in close contact with the lower surface of the substrate (W) in response to the curved lower surface shape. As a result, when the substrate (W) is transferred, the adsorption force of the adsorption portions Ab, Ab2, Ab3, Ab4, Ab5 and Ab6 for the substrate (W) increases, and thus the stability during transport of the substrate (W) may be improved.

In the above embodiments, the substrate treating apparatus of the present disclosure is described as an embodiment applied to a photo process, but the present disclosure is not limited thereto, and it is obvious to those skilled in the art that it may be applied to various processes such as an etching process, a test process, a packaging process and the like of the substrate, and this will also fall within the scope of the present disclosure.

As set forth above, in the transferring module and the substrate treating apparatus including the same according to embodiments, bending rigidity may be reduced (increase in flexibility) by providing a groove in a pad layer stacked in the middle of an adsorption portion having a multilayer structure. Accordingly, even in the case of a substrate in which a warpage phenomenon of several thousand μm or more has occurred, the adsorption portion may have increased close contact corresponding to the curved lower surface shape of the substrate, so that when the substrate is transferred, the adsorption force for the substrate increases, thereby improving the transport stability of the substrate.

While example embodiments have been illustrated and described above, it will be apparent to those skilled in the art that modifications and variations could be made without departing from the scope of the present disclosure as defined by the appended claims.

What is claimed is:

1. A transferring module comprising:
a support plate on which a substrate is supported; and
an adsorption portion disposed on the support plate, adsorbing and fixing a lower surface of the substrate, and including a groove formed inwardly concavely in one direction in an outer peripheral surface.

2. The transferring module of claim 1, wherein the adsorption portion further includes a hollow portion penetrating the adsorption portion along a vertical direction.

3. The transferring module of claim 1, wherein the adsorption portion includes a first pad layer coupled onto the support plate, a second pad layer stacked on the first pad layer, and a third pad layer stacked on the second pad layer and contacting the lower surface of the substrate when the substrate is adsorbed and fixed.

4. The transferring module of claim 3, wherein the second pad layer has greater elasticity than elasticity of the third pad layer and the first pad layer.

5. The transferring module of claim 4, wherein the groove is disposed on the second pad layer.

6. The transferring module of claim 4, wherein the groove is concave inwardly in a radial direction on an outer peripheral surface of the second pad layer.

7. The transferring module of claim 6, wherein the groove extends in a circumferential direction of the second pad layer.

8. The transferring module of claim 3, wherein the second pad layer includes a first region having a first thickness and a second region surrounding an outer side of the first region and having a second thickness, greater than the first thickness.

9. The transferring module of claim 8, wherein the groove is disposed within the second region.

10. The transferring module of claim 1, wherein the groove has a width changing at least partially toward a radial inner side of the adsorption portion.

11. A substrate treating apparatus comprising:
a module body;
an index robot disposed in the module body, and including a support plate on which a substrate is supported, and an adsorption portion disposed on the support plate, adsorbing and fixing a lower surface of the substrate, having a multilayer structure including an elastic material, and having a groove formed inwardly concavely in one direction from an outer peripheral surface; and
a vacuum module including a vacuum path connected to the adsorption portion, and a vacuum pump connected to the vacuum path and providing vacuum pressure for adsorbing and fixing the substrate.

12. The substrate treating apparatus of claim 11, wherein the adsorption portion includes a first pad layer coupled to the support plate, a second pad layer stacked on the first pad layer, and a third pad layer stacked on the second pad layer and contacting the lower surface of the substrate when the substrate is adsorbed and fixed.

13. The substrate treating apparatus of claim 12, wherein the groove is disposed on the second pad layer.

14. The substrate treating apparatus of claim 13, wherein the groove extends in a circumferential direction of the adsorption portion.

15. The substrate treating apparatus of claim 12, wherein the second pad layer includes a first region having a first thickness, and a second region surrounding an outer side of the first region and having a second thickness, greater than the first thickness.

16. The substrate treating apparatus of claim 15, wherein the groove is disposed within the second region.

17. The substrate treating apparatus of claim 11, wherein the groove, at least partially, has a width changing radially inwardly of the adsorption portion.

18. The substrate treating apparatus of claim 11, wherein the adsorption portion further includes a hollow portion penetrating the adsorption portion along a direction different from the one direction.

19. The substrate treating apparatus of claim 18, wherein the vacuum path extends inwardly of the support plate and is connected to the hollow portion.

20. A substrate treating apparatus comprising:
a load port including a loading platform on which a substrate is disposed;
a buffer module including a buffer capable of storing the substrate; and
a transferring module disposed between the load port and the buffer module and transferring the substrate between the loading platform and the buffer module,
wherein the transferring module includes,
a module body;
an index robot disposed in the module body, and including a support plate on which a substrate is supported and an adsorption portion disposed on the support plate, adsorbing and fixing a lower surface of the substrate, and having a groove formed inwardly concavely in one direction in an outer peripheral surface; and
a vacuum module including a vacuum path connected to the adsorption portion, and a vacuum pump connected to the vacuum path and providing vacuum pressure for adsorbing and fixing the substrate,
wherein the adsorption portion includes,
a first pad layer coupled to the support plate, a second pad layer stacked on and coupled to the first pad layer, and a third pad layer stacked on and coupled to the second pad layer and contacting the lower surface of the substrate when the substrate is adsorbed and fixed, wherein the second pad layer has greater elasticity than elasticity of the first pad layer and the third pad layer,
the second pad layer includes a first region having a first thickness, and a second region surrounding an outer side of the first region and having a second thickness, greater than the first thickness, and
the groove is concave inwardly in a radial direction of the adsorption portion from an outer peripheral surface of the second pad layer, and extends in a circumferential direction of the second pad layer while being disposed within the second region.
